(19) United States
(12) Patent Application Publication
(10) Pub. No.: US 2012/0042640 A1
(43) Pub. Date: Feb. 23, 2012

(54) THERMOELECTRIC DEVICE

(75) Inventors: SIGRID LIMBECK, MUCH (DE); ROLF BRÜCK, BERGISCH GLADBACH (DE)

(73) Assignee: EMITEC GESELLSCHAFT FUR EMISSIONSTECHNOLOGIE MBH, LOHMAR (DE)

(21) Appl. No.: 13/236,813

(22) Filed: Sep. 20, 2011

Related U.S. Application Data
(63) Continuation of application No. PCT/EP2010/053594, filed on Mar. 19, 2010.

(30) Foreign Application Priority Data
Mar. 20, 2009 (DE) 10 2009 013 692.4

(51) Int. Cl. F01N 5/02; H01L 35/30

(52) U.S. Cl. 60/320; 136/224

(57) ABSTRACT

A thermoelectric generator includes a plurality of thermoelectric devices, through which an exhaust gas of an internal combustion engine flows in succession. Each thermoelectric device forms at least one hot flow path for the exhaust gas and at least one cold flow path for a coolant. A plurality of p-doped and n-doped insulated semiconductor elements are connected in a targeted manner between the flow paths. At least part of the semiconductor elements in at least one of the thermoelectric devices are fixed to a flexible medium.

### CROSS-REFERENCE TO RELATED APPLICATION

This is a continuation, under 35 U.S.C. §120, of copending International Application No. PCT/EP2010/053594, filed Mar. 19, 2010, which designated the United States; this application also claims the priority, under 35 U.S.C. §119, of German Patent Application DE 10 2009 013 692.4, filed Mar. 20, 2009; the prior applications are herewith incorporated by reference in their entirety.

### BACKGROUND OF THE INVENTION

1. Field of the Invention

The present invention relates to a thermoelectric device for generating electrical energy, for example from the exhaust gas of an internal combustion engine, through the use of a generator. The generator is meant to refer, in particular, to a generator for converting thermal energy of an exhaust gas into electrical energy, that is to say a so-called thermoelectric generator.

The exhaust gas from an engine of a motor vehicle has thermal energy which can be converted into electrical energy through the use of a thermoelectric generator or apparatus in order, for example, to charge a battery or some other energy accumulator or to directly feed the required energy to electrical consumers. The motor vehicle is therefore operated with a better energetic efficiency level, and energy is available to a greater extent for the operation of the motor vehicle.

Such a thermoelectric generator has at least a plurality of thermoelectric transducer elements. Thermoelectric materials are of such a type that they can effectively convert thermal energy into electrical energy (Seebeck effect) and vice versa (Peltier effect). The “Seebeck effect” is based on the phenomenon of the conversion of thermal energy into electrical energy and is used to generate thermoelectric energy. The “Peltier effect” is the converse of the “Seebeck effect” and is a phenomenon which is associated with the adsorption of heat and its cause is related to a flow of current through different materials. The “Peltier effect” has already been proposed, for example, for thermoelectric cooling.

Such thermoelectric transducer elements preferably have a plurality of thermoelectric elements which are positioned between a so-called hot side and a so-called cold side.

Thermoelectric elements include, for example, at least two semiconductor cuboids or dies (p-doped and n-doped), which are alternately provided, on the upper side and lower side (respectively toward the hot side and toward the cold side), with electrically conductive bridges. Ceramic plates or ceramic coatings and/or similar materials serve to insulate the metal bridges and are therefore preferably disposed between the metal bridges. If a temperature gradient is made available on each side of the semiconductor cuboids or dies, a voltage potential is formed. Heat is therefore taken up on the hot side of the first semiconductor cuboid or die, wherein electrons of one side pass to an energetically higher conduction band of a following cuboid or die. On the cold side, the electrons can then release energy and pass to the following semiconductor cuboid or die with a lower energy level. As a result, an electrical current can be set, given a corresponding temperature gradient.

Attempts have already been made to make available corresponding thermoelectric generators for application in motor vehicles, in particular passenger motor vehicles. However, they have usually been very expensive to manufacture and distinguished by a relatively low efficiency level. As a result, it has not been possible to make them compatible with series production. Furthermore, it has been possible to determine that the known thermoelectric generators usually require very large installation space and can therefore only be integrated into the existing exhaust gas systems with difficulty.

### SUMMARY OF THE INVENTION

It is accordingly an object of the invention to provide a thermoelectric device, which overcomes the hereinafore-mentioned disadvantages and at least partially solves the highlighted problems of the heretofore-known devices of this general type. In particular, a thermoelectric generator is to be specified which is suitable for a variety of applications and which permits an improved efficiency level in terms of the conversion of thermal energy which is made available into electrical energy. In this context, the thermoelectric generator is to be suitable for being adapted as flexibly as possible to different performance requirements. In addition, a particularly suitable possibility for securing or connecting semiconductor elements into a thermoelectric device is also to be specified.

With the foregoing and other objects in view there is provided, in accordance with the invention, a thermoelectric generator, comprising a plurality of thermoelectric devices configured to permit an exhaust gas from an internal combustion engine to flow successively through the thermoelectric devices. Each of the thermoelectric devices forms at least one hot flow path for the exhaust gas and at least one cool flow path for a coolant. A plurality of selectively connected and insulated p-doped and n-doped semiconductor elements is disposed between the hot flow path and the cold flow path. A flexible medium is secured to at least some of the semiconductor elements in at least one of the thermoelectric devices.

A thermoelectric generator is understood, in particular, to be a composite system in a motor vehicle which has a plurality of thermoelectric devices. The thermoelectric devices are in this case, in particular, structural units which can be delineated and through which exhaust gas of an internal combustion engine can successively flow. There are therefore, for example, at least two such thermoelectric devices provided, but it is also possible to embody a thermoelectric generator in particular with 3, 4 or 5 such thermoelectric devices. Each of these thermoelectric devices forms a type of heat exchanger with one or more hot flow paths which conduct the exhaust gas through the thermoelectric device. One or more radiator flow paths are provided through which the coolant is guided through the thermoelectric device. The different flow paths are disposed in this case in such a way that an exchange of heat between the exhaust gas and coolant is made possible through a heat exchange surface. For this purpose, the flow paths can be positioned substantially parallel and/or perpendicular with respect to one another. In this context, for example, a single large flow path is preferably provided, which is penetrated by a plurality of relatively small, for example, tube-like, cold flow paths. This also ensures that the exhaust gas flows around the outside of the cold flow paths. In this boundary region between the hot flow path and the cold flow path, a plurality of p-doped and n-doped semiconductor elements are then provided. These are partially electrically insulated in such a way that selective connection of the p-doped and n-doped semiconductor elements is implemented. This is also explained below in detail. In the thermoelectric generator proposed herein, a departure is made from absorbing all of the exhaust gas energy through a single structural unit of a thermoelectric device. By using a plurality of thermoelectric devices, a multi-stage thermoelectric generator is formed, with selective utilization of the thermal conditions which are present in each respective stage being carried out in each stage. The individual thermoelectric devices are electrically insulated from one another, for example, as a structural unit, wherein the current which is respectively generated therein is conducted away. The individual thermoelectric devices are then connected in such a way that as a result a voltage of 12 to 15 V is made possible during the operation of the internal combustion engine. The individual thermoelectric devices can therefore be configured, for example, substantially in the same way with respect to the structure. In this context it is preferred that the thermoelectric devices are disposed directly one behind the other, that is to say in particular there are no further components disposed between the individual thermoelectric devices (with the exception of an exhaust gas line if appropriate).

A thermoelectric device has, in particular, at least the following:
at least one module having a first carrier layer and a second carrier layer,
an intermediate space between the first carrier layer and the second carrier layer,
an electric insulating layer on the first carrier layer and on the second carrier layer facing the intermediate space, and
a plurality of p-doped and n-doped semiconductor elements which are disposed alternately in the intermediate space between the insulating layers and are alternately electrically connected to one another.

The thermoelectric device proposed herein is combined, in particular, in a layered fashion, with, in particular, a plurality of (identical) modules to form a thermoelectric generator. In particular, a plurality of modules which are connected to one another form a thermoelectric device. In this context the thermoelectric device is disposed, in particular, in a housing in which a plurality of thermoelectric devices can also be disposed together as a structural unit in order to form a thermoelectric generator. The thermoelectric device has, in addition to the module, in particular a sealing device which seals off the intermediate space from the outside, and connecting elements for generating an electrical circuit which can conduct the electric current flowing in the module to an accumulator or consumer of a motor vehicle.

The semiconductor elements are, in particular, disposed one next to the other between two carrier layers which form, in particular, the outer boundary of the thermoelectric device. The outer carrier layers primarily form a heat conduction layer in this case which permits heat to be transferred from the thermoelectric device to the fluids which flow around the thermoelectric device. In this context, the first/second carrier layer has a heat-conducting connection to a so-called hot side, in particular to a fluid at a raised temperature, and the other (second/first) carrier layer has a heat conducting connection to a cold side, in particular to a fluid at a low temperature. As a result, a temperature potential is formed between the carrier layers through the use of the thermoelectric device. The temperature potential generates an electric current through the semiconductor elements which are alternately connected to one another, as a result of the “Seebeck effect.” The carrier layers are constructed, in particular, at least partially of steel and/or aluminum.

An intermediate space in which the semiconductor elements are disposed is provided between the carrier layers. The intermediate space therefore has, in particular, only an extent which is predefined substantially by a height and a number as well as by the configuration of the semiconductor elements.

In order to implement a selective flow of current through the p-doped and n-doped semiconductor elements, the carrier layers at least partially have an electrical insulating layer on which the semiconductor elements are secured and electrically connected to one another. In particular, an aluminum oxide layer is possible in this case as an insulating layer. With respect to the electrical insulating layer it is to be ensured that it does not excessively impede the transfer of heat from an outer side of the carrier layer to the semiconductor elements. This can also be achieved, in particular, by virtue of the fact that the electrical insulating layer is actually provided only in the region of the contact face of the semiconductor elements with the carrier layer. At any rate, such an electrical insulating layer should be made so thick that it cannot be penetrated by the device for electrically connecting the semiconductor elements to one another and the electrical insulating layer reliably prevents electrically conductive connections to the carrier layer and/or to adjacent current paths. In the first and second carrier layers, in particular, different electrical insulating layers are possible.

For example, bismuth tellurite (Bi2Te3) can be used as conductive materials for the p-doped and n-doped semiconductor elements. Furthermore, the following materials could be used [up to the following maximum temperatures in ° C.):

| | | |
|---|---|---|
| n type: | Bi2Te3 | [approx. 250° C.]; |
| | PbTe | [approx. 500° C.]; |
| | Ba0.3Co3.95Ni0.05Sb12 | [approx. 600° C.]; |
| | Bay(Co,Ni)4Sb12 | [approx. 600° C.]; |
| | CoSb3 | [approx. 700° C.]; |
| | Ba8Ga16Ge30 | [approx. 850° C.]; |
| | La2Te3 | [approx. 1100° C.]; |
| | SiGe | [approx. 1000° C.]; |
| | Mg2(Si,Sn) | [approx. 700° C.]; |
| p type: | (Bi,Sb)2TE3 | [approx. 200° C.]; |
| | Zn4Sb3 | [approx. 380° C.]; |
| | TAGS | [approx. 600° C.]; |
| | PbTe | [approx. 500° C.]; |
| | SnTe | [approx. 600° C.]; |
| | CeFe4Sb12 | [approx. 700° C.]; |
| | Yb14MnSb11 | [approx. 1000° C.]; |
| | SiGe | [approx. 1000° C.]; |
| | Mg2(Si,Sb) | [approx. 600° C.]. |

In this thermoelectric device, the two carrier layers are therefore used to bound the intermediate space and for a transfer of heat to the semiconductor elements. The semiconductor elements can be made available in this case, for example, in the manner of small cuboids or dies and/or small elongate rods made of materials with differing electrical conductivity. In each case two different semiconductor elements (p-doped and n-doped) are connected to one another electrically in such a way that together they form a series circuit. One of the two carrier layers takes up the inflowing flow of heat (hot side), while the other carrier layer outputs the outflowing flow of heat (cold side). With respect to the structure of the configuration or connection of the individual semiconductor elements, the type and/or form and/or position of the semiconductor elements can be adapted to the installation space, the flow of heat, the route of the current, etc., wherein they can, in particular, also differ from one another in this case. In particular, the thermoelectric device has one or more groups of semiconductor elements which are connected in series with one another, wherein the groups each have circuits which are independent of one another or are connected to one another through an electrical parallel circuit.

The thermoelectric generator is provided according to the invention if in at least one thermoelectric device at least some of the semiconductor elements are secured to a flexible medium. When such a thermoelectric generator is operating, a significant temperature gradient arises between the hot flow paths and the cold flow paths, which is very advantageous for the generation of energy through the use of the semiconductor elements. However, at the same time it is also necessary to take into account the fact that the operation of the internal combustion engine results in a dynamic, highly varying temperature distribution in the thermoelectric generator. During the starting phase or after the switching off of the internal combustion engine, significant temperatures and differences are also achieved. This results in the components of the thermoelectric generator of the thermoelectric device exhibiting a partially very different thermal expansion behavior. This can lead to a situation where, in particular, the semiconductor elements are subjected to stresses and there is therefore the risk of these relatively brittle materials being damaged. In order to prevent that, it is proposed that a flexible medium be provided for securing with respect to at least some of the semiconductor elements. For example, resilient and/or compressible materials can be used as the flexible material. It is therefore possible, for example, to use foams, nonwovens or similar media. Furthermore, it is preferred that this flexible medium itself have a heat-conducting structure with the result that good conduction of heat from the hot side or the cold side to the semiconductor elements is ensured. Furthermore, the medium which is flexible in this way can also be configured in such a way that specific flow paths are formed for connecting the semiconductor elements. Separate current conductors and/or suitable insulating materials can be used for this purpose. The flexible medium is selected in this case in such a way that during the operation elastic deformation of the flexible medium takes place, with the result that the different thermal expansion rates of the material are then compensated for and substantially constant pressure on the semiconductor elements is set.

In accordance with another feature of the invention, it is preferred that a pressure medium can at least partially be applied to the semiconductor elements. The pressure medium can be used, in particular, for reversing compression to flexible media which has taken place during operation. In particular, a fluid, for example an oil, is used as the pressure medium. The pressure medium also has, in particular, a high thermal conductivity, but preferably no electrical conductivity. The thermal conductivity of the pressure medium in turn ensures transfer of heat from the hot side or cold side to the semiconductor elements, and at the same time the property as an electrical insulator ensures that no undesired electrical connections of semiconductor elements are implemented. In the case of compression of the flexible medium, the pressure medium can flow into a corresponding equalizing volume and is introduced again into the flexible medium, by the provision of corresponding pressure, for example through the use of a pump or a corresponding pressurized container, when the thermal stresses are relieved.

For the sake of completeness, it will be noted that the concept disclosed herein of securing the semiconductor elements to a flexible medium, if appropriate with assistance by a pressure medium, can also be used independently of the structure of the thermoelectric generator, that is to say for example for any other “variant” of the thermoelectric device which is presented herein, for example. It is therefore possible for a semiconductor element to be secured, for example, in such a way that the semiconductor element is firstly disposed on a diffusion barrier under which solder material (for example also as a current conductor) is located. The semiconductor element is secured to the flexible pressure medium (for example a foamed material or the like) through the use of the solder. This flexible medium is secured to the wall of the flow path (and, for example, to an inner tube and/or outer tube) through the use of solder material. The flexible medium is capable in this case of compensating for differential expansion rates in the axial and/or radial directions with respect to this composite, wherein the restoring force or the maximum pressure of this composite is set through the use of a corresponding pressure medium (for example an oil). This pressure is preferably substantially the same during the operation of the thermoelectric device.

According to a further advantageous refinement of the thermoelectric device, at least some of the semiconductor elements are configured in an annular shape and are each connected by an outer circumferential surface and an inner circumferential surface to the electrical insulating layer. The term “in an annular shape” means therefore that the semiconductor element forms at least a section of an annulus. Semiconductor elements which are shaped in this way are to be proposed, in particular, for at least partially tubular thermoelectric devices. In this context, the carrier layers form the outer circumferential surface and the inner circumferential surface of a tube, with the result that a double tube wall is formed, in the interior space of which the semiconductor elements are disposed. In a thermoelectric device of such a structure, fluid flows through a duct formed by the inner circumferential surface of the tube, and another fluid overflows the thermoelectric device on the outer circumferential surface, with the result that a temperature potential can be generated across the double tube wall. The semiconductor elements are disposed inside the double tube wall and are, in particular, embodied in such a way that they are closed in a circumferential fashion in the form of an annulus. The semiconductor elements can, in particular, also be in the form of an annular segment. In this case, the semiconductor elements are also disposed next to one another or one behind the other along an axial direction of the tube. An annular or annular-segment shaped configuration of the semiconductor elements is preferred since, between cylindrical or cuboid or die-shaped semiconductor elements which are disposed one next to the other, gaps are formed between the semiconductor elements on a curved surface. The gaps become wider in the radial direction so that a smaller degree of utilization of the volume of the intermediate space is brought about. The annular shape can correspond in this case, in particular, to a circular shape, but oval embodiments are also possible. With regard to the connection, it is, for example, also possible in this case for the semiconductor elements to have a 180° annular shape, which shapes are then connected to one another electrically in an offset/alternating fashion.

According to one advantageous development of the thermoelectric device, the p-doped and n-doped semiconductor elements on the electrical insulating layer are electrically connected to one another through the use of a solder material, wherein at least one of the following conditions is met:
a) the p-doped and n-doped semiconductor elements each have flow transfer surfaces of the same size;
b) the solder material has a solder thickness and the ratio of a height of the semiconductor element to the solder thickness is greater than 5:1;
c) the solder material is an element from the group active brazing material, silver solder.

It is preferred in this case that the soldering points or soldering surfaces which serve to secure the semiconductor elements do not exceed the contact surface between the semiconductor elements and the insulating layer. The solder material is preferably applied by virtue of printing an adhesive onto the electrical insulating layer at the desired locations in order to then place the carrier layers in contact with powdery solder material, which then remains stuck at these predefined adhesive points. The grain of the solder material is selected in this case in such a way that the amount of solder material made available is precisely such that the desired contact surface which is formed by the solder material is constructed. In this context, the semiconductor elements have, on each of their contact surfaces, flow transfer surfaces which are of equal size and which are defined by the regions of the contact surfaces of the semiconductor element which are provided with solder material. As a result, contact resistances which are identical, as far as possible, are brought about between the semiconductor elements and the solder materials which function as a conductor track. In particular, in the case of semiconductor elements which are configured in an annular shape or annular segment shape and in the case of semiconductor elements with contact faces of different sizes, there is provision for flow transfer faces of equal sizes to be provided. In this context, the outer circumferential surface of the semiconductor element is generally larger than the inner circumferential surface. Accordingly, the outer flow transfer surfaces can be made narrower than the flow transfer surfaces which are disposed on the inner circumferential surface of the semiconductor elements. This is advantageous, in particular, for the manufacturing process of the thermoelectric device, during which the positioning of the conductor tracks on the one carrier layer is matched with the conductor tracks on the other carrier layer in such a way that an alternating electrical connection of the semiconductor elements is brought about, with the result that a series circuit can be generated through the use of the thermoelectric device. The reduction in the width of the flow transfer surface which is possible as a result therefore permits the fabrication tolerances during the manufacture of the conductor tracks to be made wider through the application of solder material and during the assembly of the individual components. It is therefore possible to reduce manufacturing errors and manufacturing costs in the production of the proposed thermoelectric device to a considerable degree.

The semiconductor elements which are used preferably have a height of 1 to 5 mm. This gives rise to a particularly compact configuration of the thermoelectric device and also ensures a sufficient temperature difference between the carrier layers across the intermediate space. Generally, all of the semiconductor elements are of the same height. In this context, the ratio of the height of the semiconductor elements to the solder thickness is, in particular, more than 10 to 1, preferably more than 20 to 1 and particularly preferably more than 50 to 1. The limitation of the solder thickness also promotes a compact structure of the thermoelectric device.

The solder material is preferably to be selected from the group of active brazing material, silver solder and, in particular, from the solder materials according to the European standard EN 1044 (1999): AG301, AG302, AG303, AG304, AG305, AG306, AG307, AG308, AG309, AG351, AG401, AG402, AG403, AG501, AG502, AG503, AG101, AG102, AG103, AG104, AG105, AG106, AG107, AG108, AG201, AG202, AG203, AG204, AG205, AG206, AG207, AG208. If appropriate, it is of course possible, while taking into account the particular application, to use other high-temperature resistant solders which are matched to the semiconductor materials.

According to one advantageous development of the thermoelectric device, a first contact surface between the first carrier layer and the semiconductor element and a second contact surface between the second carrier layer and the semiconductor element through the electrical insulating layer, are of different sizes and have a ratio of the first contact surface to the second contact surface of up to 1:3. In this context, the first contact surface and the second contact surface are each defined as the surface of the semiconductor element which is connected to the first or second carrier layer through the electrical insulating layer or through the solder material. As a result of the different embodiment of the first and second contact surfaces, a higher level of productivity of the fabrication of the thermoelectric device is also made possible. This increases the area of the semiconductor element which is provided for forming contact through the use of the solder material, with the result that fabrication tolerances can be made more generous, which accordingly ensures safe and fault-free production of the thermoelectric device. In particular, in the case of a tubular configuration of the module in this case a semiconductor element has a larger outer contact surface area. The semiconductor elements can accordingly have a shape which widens outward (in particular a conical shape) which ensures a contact surface which is different in such a way. Furthermore, such a condition can be met through the annular or annular-segment shaped construction of the semiconductor element. In particular, the relatively large contact surface is generally disposed on the carrier layer which the gas stream flows over. When the thermoelectric device is disposed in a motor vehicle, in which case the first carrier layer is connected to a hot side and therefore an exhaust gas stream flows over it and the second carrier layer is connected to a cold side and, in particular, a cooling liquid flows over it, the first contact surface is to be made larger than the second contact surface. This is due to the higher thermal transfer resistance at the first carrier layer which the gas stream flows over. The second carrier layer which the cooling liquid flows over can better conduct the heat, with the result that a relatively small second contact surface can be provided in this case.

According to a further advantageous embodiment, a payload capacity of the module is defined as a ratio of the sum of volumes of the semiconductor elements in the module to an encapsulated volume of the module and the payload capacity is defined as greater than 90%. The encapsulated volume of the module is defined, in particular, by the outer carrier layers and, if appropriate, further walls of the thermoelectric device or of the module. The intermediate space between the carrier layers should therefore preferably be filled as far as possible by the semiconductor elements. The payload capacity should therefore be, in particular, greater than 95% and particularly preferably greater than 98%. This is achieved, in particular, through the use of annular semiconductor elements which do not have any parting planes in the circumferential direction and accordingly permit a high payload capacity of the thermoelectric device or of the module.

According to a further advantageous development of the thermoelectric device, the semiconductor elements have electrical insulation on side surfaces which are turned toward one another, wherein the electrical insulation is formed, in particular by a layer of mica or ceramic. The term mica refers to a group of layered silicates. In this case, gaps between the semiconductor elements are filled by mica or ceramic in the form of a filler material or in the form of a coating. This insulation can preferably already be applied before the process of mounting the thermoelectric device on the semiconductor elements, with the result that the semiconductor elements can be disposed with a high packing density on the carrier layers or electrical insulating layers and support one another. An air gap between the semiconductor elements, which is known from the prior art, and is difficult to adjust in terms of fabrication technology, is therefore not necessary in this case. In this case, the insulation of the semiconductor elements from one another is therefore brought about by a separate layer, with the result that the semiconductor elements in the form of the series circuit are electrically connected to one another exclusively through the solder materials. In this context, it is particularly advantageous that the insulation between the side surfaces of the semiconductor elements has an insulation width of less than 50 μm, preferably less than 20 μm and particularly preferably less than 5 μm. This measure also gives rise to a compact structure of the thermoelectric device and also to simplified manufacture.

According to a further advantageous embodiment of the thermoelectric device, the first carrier layer has a first thickness of between 20 μm and 500 μm, preferably between 40 μm and 250 μm. In this context, the first carrier layer is disposed, in particular, on the hot side during the operation of the thermoelectric device.

In particular, only the first carrier layer has at least one axial compensation element which compensates for thermal expansion of the module in an axial direction. The axial compensation element can be embodied, for example, in the manner of a folding bellows or in accordance with a corrugated depression, with the result that compression or expansion is made possible in this region and there is a compensation for the different rate of thermal expansion between the first carrier layer (hot side) and the second carrier layer (cold side), which is brought about by the temperature difference.

In particular, there is provision that the second carrier layer has a second thickness between 200 μm and 1.5 mm, in particular between 400 μm and 1.2 mm. This second thickness, which is made significantly greater than the first thickness, ensures the dimensional stability of the thermoelectric device and of the module.

The second carrier layer advantageously has a material which has a higher thermal conductivity than the first carrier layer, with the result that the second carrier layer nevertheless exhibits comparable conduction away of heat despite the greater second thickness.

According to a further advantageous development of the thermoelectric device, a plurality of axial compensation elements are provided at distances of at maximum 10 mm in an axial direction in each case.

According to a further advantageous embodiment, the at least one module has at least one axial compensation element which is formed by at least a plurality of semiconductor elements which are disposed obliquely in an axial direction, with the result that thermal expansion of the module in an axial direction is converted at least partially into thermal expansion of the module in a radial direction. As a result of the oblique positioning of the semiconductor elements in an axial direction, a relative movement of these carrier layers can be compensated for by a change in the oblique position of the semiconductor elements as a result of a different thermal expansion of the first carrier layer compared to the second carrier layer. As a result, instead of a one-sided change of length of the module, radial expansion is brought about. In this context, the at least plurality of semiconductor elements are then at least disposed obliquely in the axial direction, while the thermoelectric device is out of operation. During operation, the semiconductor elements straighten up, due to the axial thermal expansion, in such a way that the semiconductor elements are disposed, in particular, perpendicular with respect to the carrier layers or the axial direction. This radial thermal expansion can lead to a restriction of a cross section which adjoins the outer carrier layers and through which a fluid flows, wherein this also permits the volume flow of fluid along the carrier layers to be controlled. Accordingly, fluid flows inside a thermoelectric generator, with a plurality of thermoelectric devices and a plurality of ducts through which a fluid flows and/or with carrier layers which are flowed over, can be controlled in particular in a self-regulating fashion with the result that uniform distribution of the available heat capacity in the fluid flow is ensured or promoted over all of the available surfaces of the thermoelectric devices.

According to a further advantageous development, the compensation of the thermal expansion is brought about by materials for the carrier layers which have different coefficients of thermal expansion. The carrier layer of the hot side has a correspondingly small coefficient of thermal expansion and the carrier layer of the cold side has a correspondingly high coefficient of thermal expansion.

A further particularly preferred embodiment of the thermoelectric device provides that at least a plurality of modules can be connected to one another in an axial direction. This permits the thermoelectric device to be adapted to previously defined performance requirements. This has advantages, in particular, for the manufacture and provision of thermoelectric devices for different application situations. In this context, the modules are connected to one another, in particular at least through the use of a solder connection to one another, wherein in particular electrical conductor tracks which are insulated from one another and which permit an electrical series connection of the semiconductor elements of the individual modules are to be provided. In particular, in this context, a fluid-tight connection of the individual modules to one another is also to be brought about, with the result that, in particular, corrosively acting ambient media, for example an exhaust gas, cannot penetrate into the regions between two modules. In order to provide this connection of at least a plurality of modules, a tubular configuration of the modules, in particular, is to be preferred.

A module can advantageously have a filler which seals off the intermediate space between the carrier layers from ambient media or fluids, in particular a cooling circuit or an exhaust gas. In particular, the carrier layers can also seal off the intermediate space by virtue of the fact that the first carrier layer and the second carrier layer form a (direct) connection to one another. When a plurality of modules are disposed one behind the other, it is, however, preferred to connect first carrier layers to first carrier layers and/or second carrier layers to second carrier layers, with the result that the electrical conductor tracks within each individual module can be connected to the conductor tracks of the adjacent module without a carrier layer having to be penetrated by a conductor track.

According to a further advantageous embodiment, a thermoelectric apparatus has a plurality of thermoelectric devices according to the invention, wherein the first carrier layer is connected to a hot side and the second carrier layer to a cold side.

A motor vehicle is quite particularly preferably provided with an internal combustion engine, an exhaust system, a cooling circuit and a plurality of thermoelectric devices according to the invention, wherein the first carrier layer is connected to a hot side and the second carrier layer to a cold side, and wherein in the motor vehicle the exhaust gas system is connected to the hot side and the cooling circuit to the cold side.

In addition, a thermoelectric generator in which exhaust gas flows around the outside of the at least one cold flow path is preferred. In this embodiment, it is assumed, in particular, that the cold flow path is formed, for example, in the manner of a tube. The coolant flows through the inside of the tube in this case, with the exhaust gas flowing around the outside of the tube. In this configuration it is ensured that the relatively large surface for the contact or the conduction of heat to the semiconductor elements is available to the hot exhaust gas. It is therefore possible, in particular, to compensated for the relatively poor transfer of heat from the exhaust gas to the semiconductor elements through the outer wall.

According to one development of the thermoelectric generator, it is possible for the latter to be configured in such a way that the thermoelectric devices are embodied with housings which are insulated from one another and are connected to one another through a DC/DC transformer. In such a thermoelectric generator it is possible that the individual thermoelectric devices each generate different voltages during operation. This can be reduced, for example, by virtue of the fact that the individual thermoelectric devices are embodied with different types of semiconductor elements, with the result that the latter are adapted to the exhaust gas temperatures which are to be respectively expected in the thermoelectric device, and which therefore have, for example, a corresponding temperature-dependent efficiency level. Nevertheless, differences may occur in this case, wherein a negative influence of the thermoelectric devices which are electrically connected to one another is avoided by the use of at least one DC/DC transformer. The DC/DC transformer is understood herein to be, in particular, a chopper converter. Of course, similar elements which serve the same purpose can be used.

The thermoelectric generator can also be embodied in such a way that the thermoelectric devices are each formed with semiconductor elements with different temperature-dependent efficiency levels. It is preferred in this case that each thermoelectric device is respectively embodied with a (single) type of pairs of semiconductor elements. This pairing is selected, in particular, in such a way that the semiconductor elements have the highest possible efficiency level for the temperatures prevailing during operation of the thermoelectric device. In view of the expected exhaust gas temperatures or the position of the thermoelectric devices, individual thermoelectric devices, or all of the thermoelectric devices, can respectively have a different pairing of semiconductor elements which correspond to the respectively prevailing temperatures. It is therefore possible to provide, for example near the inlet of the exhaust gas into the thermoelectric generator, semiconductor elements which have their optimum efficiency level in a range above 250° C., while, for example, semiconductor elements which have their optimum efficiency range at of approximately 80° C. to 100° C. are made available in parts of the thermoelectric generator through which the flow passes last. As a result, the overall efficiency level of the thermoelectric generator can be improved.

In accordance with a concomitant feature of the invention, a thermoelectric generator in which at least one radiator, through which the coolant flows, is provided downstream of the thermoelectric devices, is also preferred. In particular application situations, it may be appropriate if the thermoelectric generator is supplemented by a final radiator. In this context the radiator can, for example, be embodied in a manner analogous to the thermal device, wherein no further semiconductor elements are provided. The configuration of the hot and cold flow paths can be maintained just like the outer shape of the radiator. If appropriate, it is also possible for the same coolant to be used for the radiator and for the thermoelectric devices or for a common coolant circuit to be formed. As a result, the compactness of this exhaust gas treatment unit and a reduced variety of parts are preserved.

Other features which are considered as characteristic for the invention are set forth in the appended claims. Advantageous embodiments of the device according to the invention and the integration of this device into superordinate structural units are specified in the dependent claims. It is to be noted that the features disclosed individually can be combined with one another in any desired technically appropriate way and can demonstrate further embodiments of the invention.

Although the invention is illustrated and described herein as embodied in a thermoelectric device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, plan view of a motor vehicle having an embodiment variant of a thermoelectric apparatus;

FIG. 2 is an enlarged, longitudinal-sectional view of an embodiment variant of a module of a thermoelectric device;

FIG. 3 is a perspective view of an embodiment variant of a semiconductor element;

FIG. 4 is a longitudinal-sectional view of a further embodiment variant of a module of a thermoelectric device;

FIG. 5 is a perspective view of a further embodiment variant of a semiconductor element;

FIG. 6 is a longitudinal-sectional view of an embodiment variant of a thermoelectric device;

FIG. 7 is a longitudinal-sectional view of an embodiment variant of a module;

FIG. 8 is a perspective view of an embodiment variant of a multi-stage generator; and

FIG. 9 is an enlarged, plan view of a device for securing the semiconductor element.

### DETAILED DESCRIPTION OF THE INVENTION

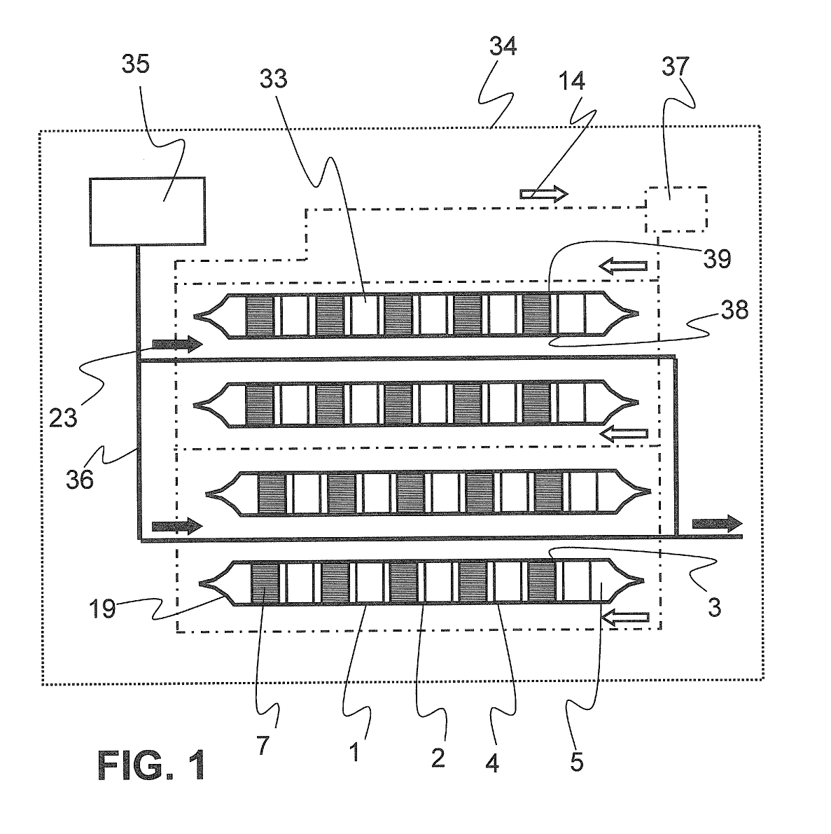

Referring now in detail to the figures of the drawing for explaining the invention and the technical field in more detail by showing particularly preferred structural variants to which the invention is not restricted, and first, particularly, to FIG. 1 thereof, there is seen an embodiment variant of a thermoelectric apparatus 33 in a motor vehicle 34 having an internal combustion engine 35 and an exhaust system 36, in which a second fluid 23, in particular an exhaust gas with a raised temperature, flows through the thermoelectric apparatus 33. The thermoelectric apparatus 33 has a plurality of thermoelectric devices 1 with modules 2. The second fluid 23 flows over these modules 2 on a hot side 38 of the thermoelectric device 1 and a first fluid 14, which is assigned to a cooling circuit 37, flows over these modules 2 on a cold side 39 of the thermoelectric device 1. The hot side 38 of the thermoelectric device 1 is bounded by a first carrier layer 3 of the module 2. Likewise, the cold side 39 is bounded by a second carrier layer 4 of the module 2. Semiconductor elements 7 are disposed in an intermediate space 5 between a first carrier layer 3 and a second carrier layer 4. Furthermore, FIG. 1 shows an encapsulated volume 19 of a module 2. The volume 19 is bounded or enclosed in this case by the first carrier layer 3 and the second carrier layer 4.

FIG. 2 shows a portion of an embodiment variant of a module 2 of a thermoelectric device 1. In this context, the module 2 is illustrated with a first carrier layer 3 and a second carrier layer 4, which have an intermediate space 5 therebetween in which the semiconductor elements 7 are alternately disposed as n-doped and p-doped semiconductor elements. These semiconductor elements 7 are alternately electrically connected to one another by solder material 10, as a result of which a series circuit of the n-doped and p-doped semiconductor elements is produced. The solder material 10 has a solder thickness 12 in this case. The solder material 10 is spaced apart from the first carrier layer 3 and second carrier layer 4 by an electrical insulating layer 6, which has an insulating layer thickness 26. The first carrier layer 3 has a first thickness 27 in this case which, in particular, is made smaller than a second thickness 28 of the second carrier layer 4. An insulation 21, with an insulation width 22, is disposed between the semiconductor elements 7. The insulation 21 is intended to prevent electrons which flow through the semiconductor elements 7 from passing through and accordingly ensures that the series connection of the semiconductor elements 7 occurs only through the solder material 10 which forms conductor tracks 42. In addition, the module 2 has an overall surface 25 which can be coated with semiconductor elements 7 and which is bounded by the outermost semiconductor elements 7. In contrast, a coated surface 24 is the sum of the surface components of the module 2 which is coated with semiconductor elements 7.

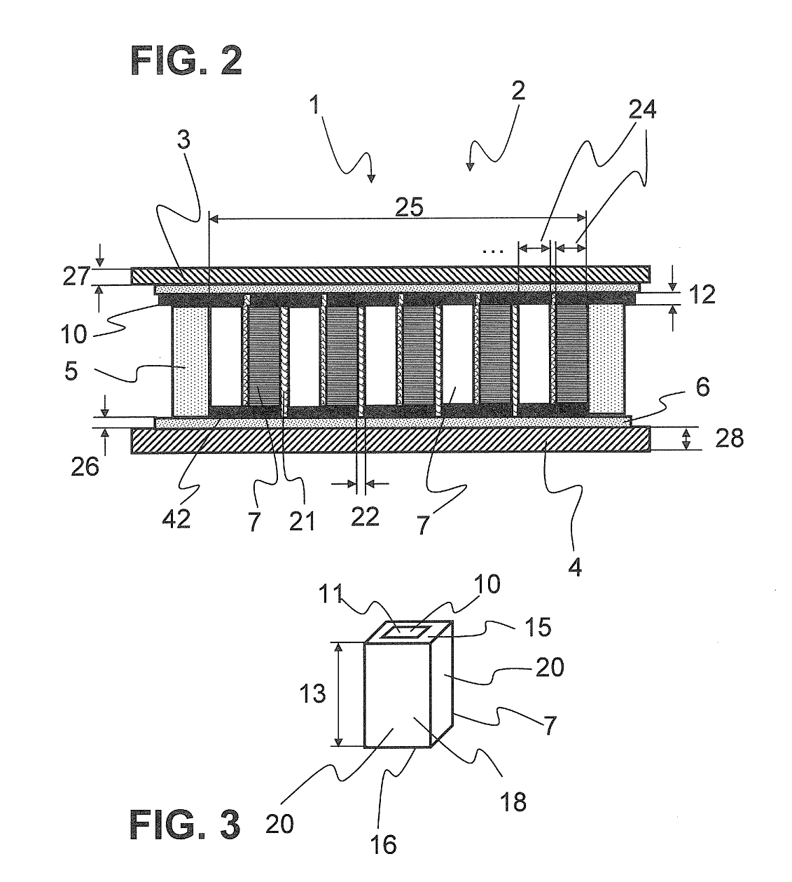

FIG. 3 shows an embodiment variant of a semiconductor element 7. The latter is embodied in this case in the form of a die or rod and has a first contact surface 15 and a second contact face 16 through which the semiconductor element 7 is connected to the first carrier layer and second carrier layer through the electrical insulating layer. In addition, the semiconductor element 7 has a flow transfer surface 11 which is formed by the semiconductor element 7 coming into contact with solder material 10, by which the individual semiconductor elements within the module are connected to one another in a series circuit. The semiconductor element 7 also has side surfaces 20 which, together with the first and second contact faces 15, 16, bound a volume 18 of the semiconductor element 7. The semiconductor element 7 also has a height 13.

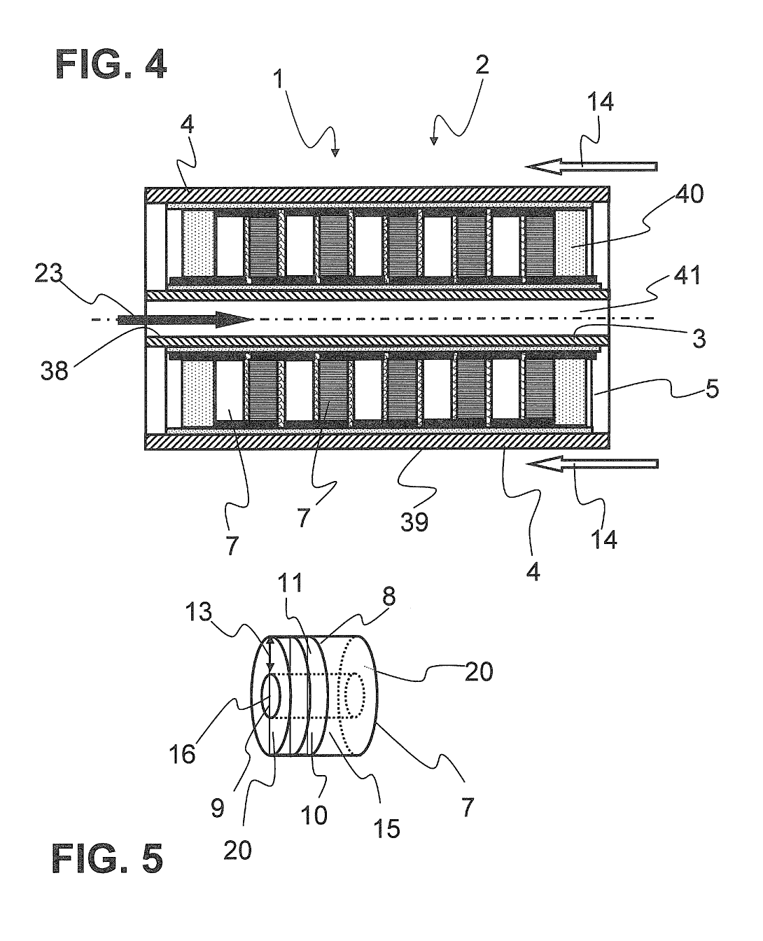

FIG. 4 shows a further embodiment variant of a module 2 of a thermoelectric device 1, in which a tubular embodiment of the thermoelectric device 1 and/or of the module 2 is shown. In particular, a second fluid 23 flows through the tubular module 2, through an inner duct 41. As a result, in the embodiment variant shown therein, the inner duct 41 forms the hot side 38 of the thermoelectric device 1. A first fluid 14 flows over the cold side 39 of the thermoelectric device 1, as a result of which a temperature potential is formed through the use of the semiconductor elements 7. The inner circumferential surface of the tube and therefore the inner duct 41 is formed by the first carrier layer 3, while the outer circumferential surface of the module 2 is formed in this case by the second carrier layer 4. The intermediate space 5 is sealed off by a filler material 40 in order to limit the intermediate space 5 and to provide protection against the ingress of possibly corrosively acting fluids.

FIG. 5 shows a further embodiment variant of a semiconductor element 7. In this case, an annular semiconductor element 7 is shown with an outer circumferential surface 8 and an inner circumferential surface 9. This semiconductor element 7 is, in particular, suitable for use in a tubular thermoelectric device, for example according to FIG. 4. In this case, the semiconductor element 7 is connected by a first contact surface 15 to the first carrier layer and by a second contact surface 16 to the second carrier layer. The semiconductor element 7 also has side surfaces 20 and a height 13 which is formed between the inner circumferential surface 9 and the outer circumferential surface 8. The annular semiconductor element 7 has a flow transfer surface 11 on its outer circumferential surface 15, and a further flow transfer surface on its inner circumferential surface 16, which are formed by the contact with the solder material 10.

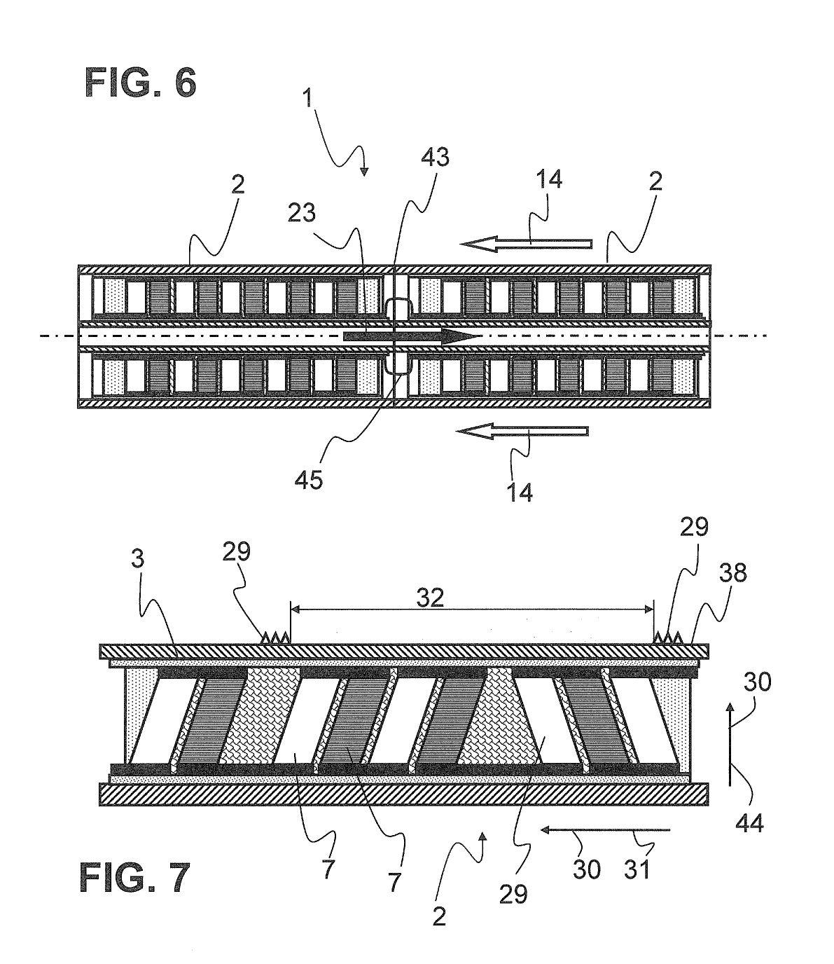

FIG. 6 shows an embodiment variant of a thermoelectric device 1, wherein a plurality of modules 2 are connected to one another by solder connections 43 to form a thermoelectric device 1. In this context it is necessary, in particular, to ensure that the individual modules 2 are sealed off from possibly corrosively acting fluids. In this case, as a result of the plurality of modules 2 being connected to form a thermoelectric device 1, the thermoelectric device 1 can be adapted to different requirements in terms of the provision of electrical energy or conversion of thermal energy which is present into electrical energy. The individual modules 2 are electrically connected to one another through a connecting device 45 with the result that a series connection of the semiconductor elements through a plurality of modules 2 within the thermoelectric device 1 is also ensured.

FIG. 7 shows a portion of a preferred embodiment variant of a module 2, wherein semiconductor elements 7 which are positioned obliquely with respect to an axial direction 31 are provided in this case. The semiconductor elements 7 form an axial compensation element 29, with the result that thermal expansion 30 in the axial direction 31 can be at least partially converted into thermal expansion 30 in a radial direction 44 by changing the oblique positioning of the semiconductor elements 7. In addition, axial compensation elements 29 are provided on the first carrier layer 3 (hot side 38) and are disposed at a distance 32 from one another.

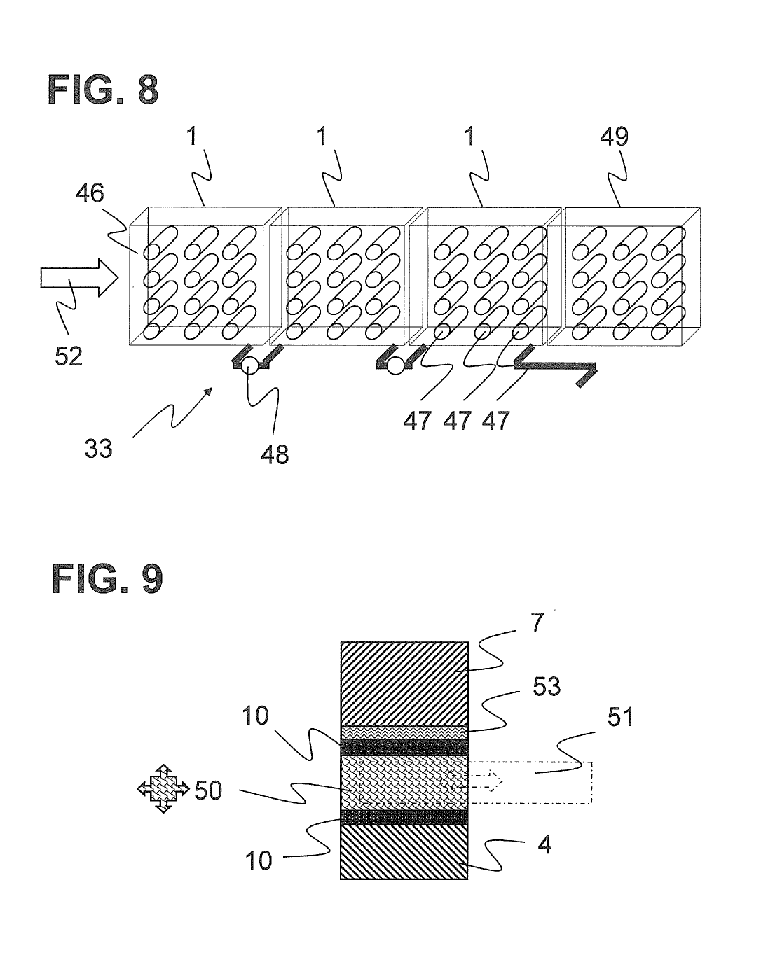

FIG. 8 shows an embodiment variant of a multi-stage generator 33. The latter is embodied in this case with three thermoelectric devices 1 which are disposed directly one behind the other in a flow direction 52 of the exhaust gas. The thermoelectric devices form a hot flow path 46 for the exhaust gas which is penetrated by a plurality of tube-like or tube-shaped cold flow paths 47 through which the coolant flows in the manner of a cross-flow heat exchanger. The individual thermoelectric devices 1 are connected in series, in such a way that DC/DC transformers 48 are also provided in this case. A radiator 49, which is formed substantially with a structure identical to that of the thermoelectric devices 1, is disposed downstream of the thermoelectric devices 1 in the direction of flow 52, but in this case the complex structure of the cold flow paths 47 is not implemented. Nevertheless, a particularly compact embodiment can be implemented. The hot flow path 46 can be embodied, for example, with the dimensions 90 mm×50 mm. The cold flow paths 47 can be embodied in the manner of double-walled tubes with an inner diameter of 6 mm and an outer diameter of 14 mm. It is therefore possible, for example, when the exhaust gas enters at a temperature of 500° C. and exits at a temperature of 80° C., for approximately 0.1 V to be generated in the thermal pair, with the result that a voltage of 12 to 15 volts is obtained per thermoelectric device 1. The individual thermoelectric devices 1 are electrically insulated from one another in this case.

FIG. 9 shows a portion of a device for securing a semiconductor element 7, for example to a layer 4 on the cold side, or to the inner wall of a cold flow path which is configured in a tubular shape. Solder material 10 is provided on this layer 4 on the cold side and a flexible medium 50, for example a metal foam or a sintered material, is secured to the solder material 10. The flexible medium 50 can be deformed, as a result of which compensation movements are made possible, in particular in the axial and/or radial direction of the flow path. The “dimensional rigidity” or the deformation behavior is implemented by a pressure medium 51 which can be introduced (selectively) into the flexible medium 50. This pressure medium 51 is, for example, an oil which has no electrical conductivity. It is also preferred for the flexible medium 50 and the pressure medium 51 to have good thermal conductivity values, ensuring that heat is transferred from the layer 4 on the cold side to the semiconductor element 7. The semiconductor element 7 is also secured to this flexible medium 50 through a diffusion layer 53 and a solder material 10. If radial tensions then occur during operation, the flexible medium 50 can be compressed and the pressure medium 50 exits, for example into an equalizing volume. When the device cools down again, the shrinkage can be compensated for by virtue of the fact that the pressure medium 51 enters into the flexible medium 50 again, and therefore results in expansion of the flexible medium 50.

1. A thermoelectric generator, comprising:
a plurality of thermoelectric devices configured to permit an exhaust gas from an internal combustion engine to flow successively through said thermoelectric devices;
each of said thermoelectric devices forming at least one hot flow path for the exhaust gas and at least one cool flow path for a coolant;
a plurality of selectively connected and insulated p-doped and n-doped semiconductor elements disposed between said hot flow path and said cold flow path; and
a flexible medium secured to at least some of said semiconductor elements in at least one of said thermoelectric devices.

2. The thermoelectric generator according to claim 1, which further comprises a pressure medium to be applied at least partially to said semiconductor elements.

3. The thermoelectric generator according to claim 1, wherein the exhaust gas flows around the outside of the at least one cold flow path.

4. The thermoelectric generator according to claim 1, wherein said thermoelectric devices have housings insulated from one another and are connected to one another through a DC/DC transformer.

5. The thermoelectric generator according to claim 1, wherein said semiconductor elements of each of said thermoelectric devices have different temperature-dependent efficiency levels.

6. The thermoelectric generator according to claim 1, which further comprises at least one radiator disposed downstream of said thermoelectric devices and configured for conducting a flow of coolant through said at least one radiator.
